(19) United States
(12) Patent Application Publication
(10) Pub. No.: US 2008/0083562 A1
(43) Pub. Date: Apr. 10, 2008

(54) INTEGRATED EMC GASKET FOR ELECTRICAL ENCLOSURE

(75) Inventors: Joseph Kuczynski, Rochester, MN (US); Kevin A. Splittstoesser, Stewartville, MN (US); Timothy J. Tofil, Rochester, MN (US); Paul A. Vermilyea, Rochester, MN (US)

Correspondence Address: CANTOR COLBURN LLP - IBM ROCHESTER DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/538,825

(22) Filed: Oct. 5, 2006

(51) Int. Cl. H05K 9/00

(52) U.S. Cl. 174/350

(57) ABSTRACT

An integrated EMC gasket for an electrical enclosure includes an electrical housing substrate molded of a thermoplastic having a conductive network of fibers above a percolation limit of the fibers, and an EMC gasket insert molded into the electrical housing substrate, the gasket including a silicone foam core with a conductive fabric cover.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

The present invention relates generally to an EMC gasket for an electrical enclosure. More particularly, the present invention is directed to an integrated EMC gasket for an electrical enclosure to provide a level of EMC shielding.

2. Description of Background

The generation of electromagnetic interference (EMI) is one of many concerns that arises in electrical systems as circuit feature size shrinks, operating frequencies increase and packaging densities grow larger. Electronic circuit packaging designs should thus also be compatible with structures and configurations that are employed to prevent the leakage of electromagnetic interference. To whatever extent possible, packaging designs should also include structures which actually contribute positively to the containment of electromagnetic interference. There is an ever increasing problem of electromagnetic interference caused by such devices. Virtually every electronic device, intentionally or not, emits some form of electromagnetic radiation. While this condition could be tolerated when few devices existed within electrical enclosures, the increasing number of electronic devices has made the problem more acute. The problem has been exacerbated by the “improvement” in semiconductor devices which allows them to operate at higher speeds, generally causing emission in the higher frequency bands where interference is more likely to occur. Successful minimization of the interference problem, sometimes referred to as “electromagnetic compatibility” or “EMC”, generally requires that emissions from a given device be reduced by shielding and other means, and that shielding be employed to reduce the sensitivity of a device to fields from other devices. Since shielding helps to reduce sensitivity to external fields as well as reduce emissions from the device, it is a common approach to a solution of the problem.

In newer high speed packages it is necessary to use a metallic type of gasket to provide better conduction among panels of an electrical enclosure in which printed circuit cards are engaged. EMC gaskets typically consist of a metallized fabric wrapped over a foam core. A pressure sensitive adhesive (PSA) is applied to the backside of the gasket in order to facilitate adhesion to a panel of a business equipment enclosure or other electronic device housing. Unfortunately, the PSA requires a substantial fraction of real estate on a gasket (e.g., approaching 60-70% of the backside surface area for rectangular, D shape, and C-fold gaskets) to ensure adequate gasket adhesion. Since the PSA is inherently non-conductive, the effective surface area in contact with the panel is dramatically reduced thereby decreasing the EMC performance of the gasket. Moreover, EMC gaskets are prone to be sheared from the substrate during assembly of the enclosure. Once the metallic gasket is damaged, the gasket does not provide the intended function. Moreover, if the gasket actually breaks, the gasket poses a threat for a potential short. Although this can be remedied by increasing the PSA footprint (e.g., surface area contact), such an approach is extremely detrimental to EMC performance.

### SUMMARY OF THE INVENTION

The shortcomings of the prior art are overcome and additional advantages are provided through the provision of an integrated EMC gasket for an electrical enclosure. The integrated EMC gasket includes an electrical housing substrate molded of a thermoplastic having a conductive network of fibers above a percolation limit of the fibers, and an EMC gasket molded with the electrical housing substrate, the gasket including a silicone foam core with a conductive fabric cover.

In another exemplary embodiment, a method of integrating an EMC gasket with an electrical enclosure is provided. The method includes molding an electrical housing substrate of a thermoplastic having a conductive network of fibers above a percolation limit of the fibers; covering a silicone foam core with a conductive fabric to form an EMC gasket; and insert molding the EMC gasket with the electrical housing substrate.

In yet another exemplary embodiment, an integrated EMC gasket for an electrical enclosure is provided. The integrated EMC gasket includes an electrical housing substrate molded of a polycarbonate/acrylonitrile butadiene styrene (PC/ABS) blend having a conductive network of fibers including stainless steel above a percolation limit of the fibers; and an EMC gasket insert molded with the electrical housing substrate. The gasket includes a silicone foam core with a conductive fabric cover. At least an entire bottom surface of the EMC gasket makes electrical surface contact with the electrical housing substrate.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a perspective view of an access cover for an electrical enclosure or a central electronics complex (CEC) for a computer illustrating a prior art pressure sensitive adhesive backed EMC gasket adhered thereto according to the prior art; and

FIG. 2 is a cross-sectional view of a panel for an electrical enclosure (e.g., a CEC) illustrating an exemplary embodiment of an EMC gasket integrated therewith in accordance with the present invention.

The detailed description explains the preferred embodiments of the invention, together with advantages and features, by way of example with reference to the drawings.

### DETAILED DESCRIPTION OF THE INVENTION

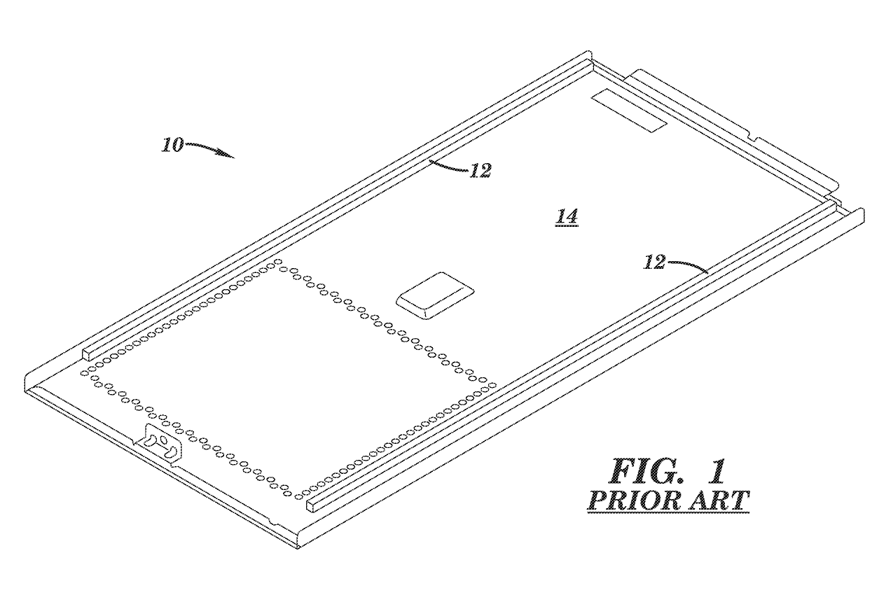

Turning now to the drawings in greater detail, it will be seen that in FIG. 1 there is illustrated a perspective view of an access cover 10 for an electrical enclosure or a central electronics complex (CEC) for a computer (both not shown) illustrating a pair of conventional pressure sensitive adhesive (PSA) backed EMC gaskets 12 adhered thereto according to the prior art. The pair of PSA backed EMC gaskets 12 extend along opposite longitudinal ends of the CEC access cover 10 to provide an EMC connection upon assembly with the remaining electrical enclosure (not shown). As illustrated, the gaskets 12 are disposed atop a surface 14 defining the cover 10. In particular, the gaskets 12 are affixed to the surface 14 of the cover 10 using the PSA (not shown) on a backside of each gasket 12.

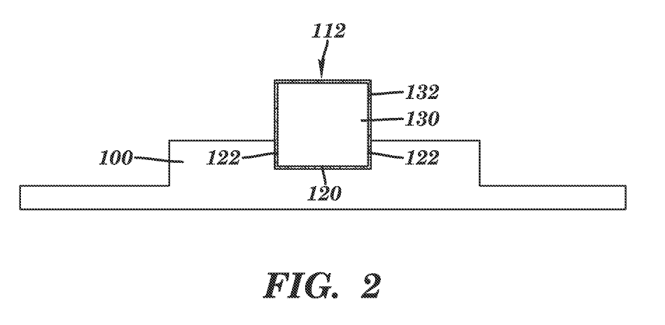

FIG. 2 is a cross-sectional view of a panel 100 for an electrical enclosure (e.g., a CEC) illustrating an exemplary embodiment of an EMC gasket 112 integrated therewith in accordance with the present invention. The panel 100 is formed of a thermoplastic having a conductive network of fibers including stainless steel above a percolation limit of the fibers.

In sharp contrast to the gasket 12 affixed to a major surface defining the panel 10 of FIG. 1, FIG. 2 is a cross-sectional view illustrating a molded-in recess 116 of the panel 100 for retaining the EMC gasket 112 across the entire bottom surface 120 of the gasket 112, as well as partially up the sides 122 of the gasket 1 12. Since the gasket 112 is “adhered” to the panel 100 formed of a plastic substrate as a result of being insert molded into the cover, the PSA is obviated. Moreover, the intimate contact between the gasket fabric and the conductive network of fibers within the plastic substrate improves the EMC effectiveness of the gasket.

More specifically, EMC gasket 112 includes a silicone foam core 130. An entire outer surface defining the silicone foam core 130 is covered with an electrically conductive fabric 132. In exemplary embodiments, the conductive fabric is composed of a polyester, polyamide or other suitable thermoplastic resin or cloth overplated with either nickel or silver

The panel 100 is an electrical housing substrate molded of a thermoplastic having an electrically conductive network of fibers above a percolation limit of the fibers. The thermoplastic is a base resin including the electrically conductive network of fibers. In exemplary embodiments, the conductive fibers include stainless steel fibers, for example, but is not limited thereto. The thermoplastic includes Faradex®. Faradex® is a ready-to-mold thermoplastic commercially available from LNP (a GE Plastics Company) that consists of a base resin plus highly conductive stainless steel fibers. The fibers form an electrically conductive network above the percolation limit. Coupled with their high aspect ratio, Faradex fibers provide adequate EMI shielding at very low filler levels (on the order of 0.7-1.4 vol. %).

Faradex® products are available in a blend of polycarbonate and acrylonitrile butadiene styrene (PC/ABS) yielding high strength and high flow for thinwall molding PC/ABS blends, the workhorse resin for business equipment and electronic housings. Covers or enclosures molded from Faradex® PC/ABS blends provide an electrically conductive substrate to which a traditional EMC gasket can be mated. By insert molding a silicone core, fabric-over-foam gasket into electrical housings molded from Faradex®, traditional PSA backed EMC gaskets can be eliminated. An integrated gasket provides greater surface contact with the enclosure (e.g., along the entire bottom surface 120 of the gasket 112, as well as partially up the sidewalls 122) and virtually eliminates the potential for shear failure of the gasket. With a traditional PSA-backed gasket, the shear force only needs to be greater than the PSA bond strength (typically less than 1 lb/in width). In order to shear an exemplary integrated gasket 112 from the enclosure 100, the tear strength of the fabric 132 and foam core 130 must be exceeded. The tear strength of the gasket 112 is well over an order of magnitude greater than PSA bond strength of the conventional gasket 12. However, if additional retention strength is required, the profile of both the gasket and the molded cavity can be modified in order to meet design specifications.

Faradex® compounds provide electromagnetic and radio frequency interference (EMI/RFI) attenuation in applications from electronics to material handling. Conductive fibers form the conductive network required for EMI/RFI shielding (e.g., EMI/RFI shielding capabilities between 40-60 dB and higher from 30-1000 MHz). Faradex® compounds can also be used in applications where electrostatic discharge (ESD) is required. Faradex® compounds provide mechanical properties, part weight and a design freedom similar to standard unfilled base resins. They avoid costly secondary steps, offering total system cost reduction.

Accomplished with electrically conductive stainless steel fibers at modest loading levels, the panels 100 formed of Faradex® compounds can also be used in applications where electrostatic discharge (ESD) is required. The mechanical properties of Faradex® compounds are similar to standard unfilled base resins. If needed, additional glass or carbon fiber reinforcement is available to enhance strength and stiffness or control mold shrinkage. In addition, Faradex® compounds can be compounded for flame retardancy (FR), including non-halogenated FR compounds.

Use of Faradex® compounds helps control costs in that EMI/RFI attenuation occurs throughout the part, thereby eliminating the need for secondary conductive coatings (e.g., a conductive paint or vacuum deposited metallization), or attachment of conductive fabrics or sheet metal. Design freedom of injection molding offers advantages for intricate part design, where metallic sprays or conductive netting are far less effective. Because the conductivity permeates the entire part, it cannot be disrupted by surface scratches or nicks.

In order to minimize a resin-rich surface and ensure that the surface resistance values of Faradex® are low enough to provide adequate grounding of the in-mold gasket, the Faradex® can be molded on the cool side of the melt specification and the mold temperature can be decreased in order to freeze out the resin prior to packing it on the surface. Such trivial process modifications can decrease the surface resistivity two orders of magnitude. In this case, the surface of the part provides adequate grounding in the as-molded state (i.e., no post-molding, secondary operation is required to expose the stainless steel fibers to ensure grounding). Further, if it is deemed necessary, features can be incorporated into the mold to disrupt the melt front to create a fiber-rich surface. Alternatively, a snap-off runner or zipper can be molded into the gasket channel which, upon removal, would expose the fibers and guarantee intimate metal-to-metal contact (e.g., between gasket 112 and panel 100). Should this be required, the gasket must be inserted following the molding process.

It will be recognized that in alternative exemplary embodiments that the foam core material may include silicone, polyether urethane, polyester urethane, ethylene propylene diene monomer (EPDM), thermoplastic elastomers, or a combination including at least one of the foregoing materials. Further the plastic used for the housing substrate may include polycarbonate, acrylonitrile butadiene styrene (ABS), polyvinyl chloride (PVC), Noryl (polyphenylene oxide), polyamides or combinations of at least one of the foregoing materials. Lastly, the conductive network of fibers may include stainless steel, nickel powder/flake, carbon fiber, carbon nanotubes, silver (Ag) powder/flake or combinations of at least one of the foregoing materials.

Utilizing the above approach to form an exemplary integrated EMC gasket with an electrical enclosure results in a multitude of benefits. First, elimination of the PSA from traditional EMC gaskets provides a part cost savings, as well as reliability enhancement by eliminating potential for corrosion of metal-coated fabric in high temperature and humidity environments. Secondly, the exemplary integrated EMC gasket eliminates a secondary operation of application of the gasket to the substrate via insert molding. Thirdly, the exemplary integrated EMC gasket eliminates expensive plastic metallization processes (e.g., either vacuum metallization, plating, or conductive paint). Fourthly, the exemplary integrated EMC gasket provides enhanced reliability as the insert molded gasket has a tear strength much greater than the bond strength of a conventional PSA-backed gasket. Fifthly, the exemplary integrated EMC gasket provides increased EMI shielding due to greater surface contact with the electrical enclosure having a recess to receive the integrated EMC gasket therewith. By integrating a gasket into the enclosure, surface contact with the enclosure is increased (thereby increasing gasket effectiveness) and the tendency to shear the gasket from the enclosure is effectively eliminated or at least substantially reduced. Lastly, the exemplary integrated EMC gasket enhances design flexibility, as the insert molded gasket can be positioned around bosses, standoffs, retaining features, etc.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. An integrated EMC gasket for an electrical enclosure comprising:
an electrical housing substrate molded of a plastic having an electrically conductive network of fibers above a percolation limit of the fibers; and
an EMC gasket molded with the electrical housing substrate, the gasket including a foam core material with a conductive fabric cover.

2. The integrated EMC gasket of claim 1, wherein the plastic is a thermoplastic including a base resin and the electrically conductive network of fibers includes stainless steel fibers.

3. The integrated EMC gasket of claim 2, wherein the thermoplastic includes Faradex®.

4. The integrated EMC gasket of claim 3, wherein the electrical housing substrate is molded of a Faradex® polycarbonate and acrylonitrile butadiene styrene (PC/ABS) blend.

5. The integrated EMC gasket of claim 1, wherein the EMC gasket is insert molded with the electrical housing substrate.

6. The integrated EMC gasket of claim 1, wherein at least an entire bottom surface of the EMC gasket makes electrical surface contact with the electrical housing substrate.

7. The integrated EMC gasket of claim 1, wherein an entire bottom surface and at least a portion of opposing side surfaces of the EMC gasket makes electrical surface contact with the electrical housing substrate.

8. The integrated EMC gasket of claim 1, wherein the foam core material includes one of silicone, polyether urethane, polyester urethane, ethylene propylene diene monomer (EPDM), thermoplastic elastomers, or a combination including at least one of the foregoing materials.

9. The integrated EMC gasket of claim 1, wherein the plastic includes one of polycarbonate, acrylonitrile butadiene styrene (ABS), polyvinyl chloride (PVC), Noryl (polyphenylene oxide), polyamides or combinations of at least one of the foregoing materials.

10. The integrated EMC gasket of claim 1, wherein the conductive network of fibers includes one of stainless steel, nickel powder/flake, carbon fiber, carbon nanotubes, silver (Ag) powder/flake or combinations of at least one of the foregoing materials.

11. A method of integrating EMC gasket with an electrical enclosure, the method comprising:
molding an electrical housing substrate of a thermoplastic having an electrically conductive network of fibers above a percolation limit of the fibers;
covering a silicone foam core with a conductive fabric to form an EMC gasket; and
insert molding the EMC gasket with the electrical housing substrate.

12. The method of claim 11, wherein the thermoplastic is a base resin and the electrically conductive network of fibers includes stainless steel fibers.

13. The method of claim 12, wherein the thermoplastic includes Faradex®.

14. The method of claim 13, wherein the electrical housing substrate is molded of a Faradex® polycarbonate and acrylonitrile butadiene styrene (PC/ABS) blend.

15. The method of claim 11, wherein at least an entire bottom surface of the EMC gasket makes electrical surface contact with the electrical housing substrate.

16. The method of claim 11, wherein an entire bottom surface and at least a portion of opposing side surfaces of the EMC gasket makes electrical surface contact with the electrical housing substrate.

17. An integrated EMC gasket for an electrical enclosure comprising:
an electrical housing substrate molded of a polycarbonate/acrylonitrile butadiene styrene (PC/ABS) blend having an electrically conductive network of fibers including stainless steel above a percolation limit of the fibers; and
an EMC gasket insert molded with the electrical housing substrate, the gasket including a silicone foam core with a conductive fabric cover, wherein at least an entire bottom surface of the EMC gasket makes electrical surface contact with the electrical housing substrate.

18. The integrated EMC gasket of claim 17, wherein an entire bottom surface and at least a portion of opposing side surfaces of the EMC gasket makes electrical surface contact with the electrical housing substrate.
